(19) United States
(12) Patent Application Publication
(10) Pub. No.: US 2025/0147363 A1
(43) Pub. Date: May 8, 2025

(54) ARRAY SUBSTRATE AND LIQUID CRYSTAL DISPLAY PANEL

(71) Applicant: Guangzhou China Star Optoelectronics Semiconductor Display Technology Co., Ltd., Guangdong (CN)

(72) Inventor: Paijie CHEN, Guangzhou (CN)

(21) Appl. No.: 17/799,659

(22) PCT Filed: Jul. 29, 2022
(86) PCT No.: PCT/CN2022/109130

§ 371 Date: Jan. 27, 2025

(30) Foreign Application Priority Data
Jul. 11, 2022 (CN) 202210813516.2

(51) Int. Cl. G02F 1/1339; G02F 1/1333; H10D 86/60

(52) U.S. Cl. CPC G02F 1/1339; G02F 1/133345; H10D 86/60

(57) ABSTRACT

An array substrate and a liquid crystal display panel are provided. The array substrate has a device region and a sealant region enclosing the device region. The array substrate further includes a substrate and an array driving layer. The array substrate includes at least one conductive layer and at least one insulation layer located on a side of the conductive layer away from the substrate. Wherein, the insulation layer is only located in the device region correspondingly; or the insulation layer is correspondingly located in the device region and the sealant region, and a number of layers of the insulation layer located in the sealant region is less than a number of layers of the insulation layer located in the device region.

### TECHNICAL FIELD

The present invention relates to the field of display technology, and specifically to an array substrate and a liquid crystal display panel.

### BACKGROUND

Thin film transistor liquid crystal displays (TFT-LCDs) are formed by filling liquid crystal in middle of array substrates and color filter substrates through one-drop filling (ODF) processes. Furthermore, the array substrates and the color filter substrates are sealed and bonded by disposing sealant at positions corresponding to non-display regions between array substrates and color filter substrates. In order to prevent peeling-off between the array substrates and the color filter substrates, certain adhesive widths of the sealant need to be ensured, which are generally about 1300 μm, so as to provide sufficient adhesive force.

However, with rapid development of thin-film transistor liquid crystal display technology, as thin-film transistor liquid crystal displays with narrow bezels are becoming more and more popular, non-display regions around the thin film transistor liquid crystal displays are required to be narrower and narrower, thereby widths of the sealant also being required narrower and narrower, and even more less than 300 μm is required. As illustrated in FIG. 1, in narrow bezel technology, a signal lines 2′ at periphery of some display region of an array substrate 1′ is disposed under a sealant 3′ to reduce a width of a bezel. However, as a number of film layers on the signal line 2′ in the array substrate 1′ increases, a contact surface M between the array substrate 1′ and the sealant 3′ is close to a plane, i.e., an adhesive area between the sealant 3′ and the film layers is gradually decreased. In FIG. 1, which presents that a length decreases, wherein the length is that: L1>L2>L3>L4>L5. When the width of the sealant is narrow, the sealant cannot provide enough adhesive force, which leads to peeling-off easily appearing on the array substrate and the color filter substrate.

Therefore, a technical solution is needed to provide to solve the aforesaid problems.

### SUMMARY

### Technical Problem

The present invention provides an array substrate and a liquid crystal display panel, which can solve the technical problem that the array substrate and the color filter substrate in current liquid crystal displays with narrow bezels are easily peeled off due to insufficient adhesive force of the sealant.

### Solution to Problem

### Technical Solution

In order to solve the problems mentioned above, the present invention provides the technical solutions as follows.

One embodiment of the present invention provides an array substrate, having a device region and a sealant region enclosing the device region. The array substrate further includes:
a substrate;
an array driving layer disposed on the substrate, wherein the array substrate includes at least one conductive layer and at least one insulation layer located on a side of the at least one conductive layer away from the substrate, and the at least one conductive layer includes a conductive pattern located in the sealant region; and
wherein the insulation layer is only located in the device region correspondingly; or the insulation layer is correspondingly located in the device region and the sealant region, and a number of layers of the insulation layer located in the sealant region is less than a number of layers of the insulation layer located in the device region.

Optionally, in some embodiments of the present invention, a surface area of the array driving layer is greater than a projection area of an orthogonal projection of the array driving layer on the substrate in the sealant region.

Optionally, in some embodiments of the present invention, in the sealant region, the at least one insulation layer is disposed on a side of the conductive pattern away from the substrate, the insulation layer includes a first coverage layer corresponding to the conductive pattern, a surface area of the first coverage layer is greater than a projection area of an orthogonal projection of the first coverage layer on the substrate.

Optionally, in some embodiments of the present invention, in the sealant region, the at least one conductive layer is disposed on a side of the conductive pattern away from the substrate, the conductive layer includes a second coverage layer corresponding to the conductive pattern, and a surface area of the second coverage layer is greater than a projection area of an orthogonal projection of the second coverage layer on the substrate.

Optionally, in some embodiments of the present invention, in the sealant region, a distance of a boundary of the insulation layer to the device region is less than a distance of a boundary on a side of the sealant region away from the device region to the device region, and an orthogonal projection of the insulation layer on the substrate covers an orthogonal projection of the conductive pattern on the substrate; and/or

in the sealant region, the at least one conductive layer is disposed on a side of the conductive pattern away from the substrate, a distance of a boundary of the conductive layer to the device region is less than the distance of the boundary on the side of the sealant region away from the device region to the device region, and the orthogonal projection of the insulation layer on the substrate covers the orthogonal projection of the conductive pattern on the substrate.

Optionally, in some embodiments of the present invention, the conductive pattern includes a bottom surface facing toward the substrate and a lateral surface connected to the bottom surface, an included angle formed between the lateral surface and the bottom surface ranges from 60°-90°.

One embodiment of the present invention further provides a liquid crystal display panel, which includes the aforesaid array substrate, and further includes an opposite substrate disposed opposite to the array substrate, a liquid crystal layer located between the array substrate and the opposite substrate, and a sealant for bonding the array substrate and the opposite substrate.

Wherein, the sealant is bonded to a part of the array substrate corresponding to the sealant region.

Optionally, in some embodiments of the present invention, a contact area between the array substrate and the sealant is greater than a projection area of an orthogonal projection of the sealant on the array substrate.

Optionally, in some embodiments of the present invention, a part of the sealant away from the device region contact to the substrate along the conductive layer and/or the lateral surface of the insulation layer.

Optionally, in some embodiments of the present invention, an orthogonal projection of the insulation layer on the substrate is within the device region, and the sealant directly contacts to the conductive layer.

### Advantageous Effect of Present Disclosure

### Advantageous Effect

Beneficial effects of the present invention is that in the array substrate and the liquid crystal display panel provided by the present invention, by reducing the number of the layers of the insulation layer on the conductive pattern located in the sealant region, and by using the level difference formed by the conductive pattern, the contact area between the sealant and the array substrate is increased, and the adhesive force between the sealant and the array substrate is improved, thereby solving the problem of insufficient adhesive force between the sealant and the array substrate.

### BRIEF DESCRIPTION OF DRAWINGS

### Description of Drawings

To more clearly illustrate embodiments or the technical solutions of the present invention, the accompanying figures of the present invention required for illustrating embodiments or the technical solutions of the present invention will be described in brief. Obviously, the accompanying figures described below are only part of the embodiments of the present invention, from which those skilled in the art can derive further figures without making any inventive efforts.

FIG. 1 is a structural schematic diagram of an array substrate bonded to a sealant in the prior art.

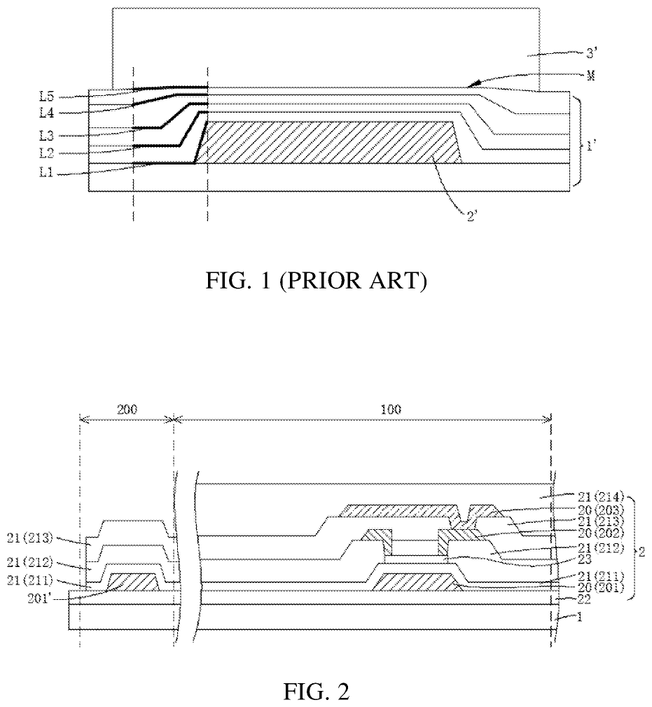

FIG. 2 is a structural schematic diagram of an array substrate provided by one embodiment of the present invention.

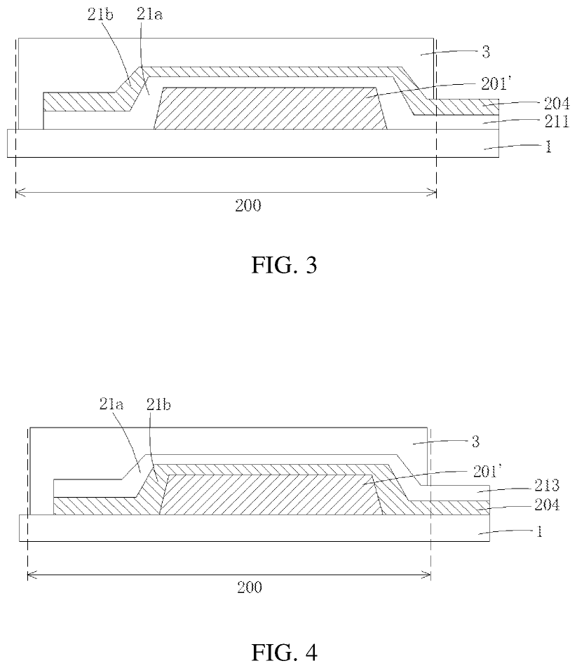

FIG. 3 is a structural schematic diagram of a first kind of a sealant region of the array substrate provided by one embodiment of the present invention.

FIG. 4 is a structural schematic diagram of a second kind of the sealant region of the array substrate provided by one embodiment of the present invention.

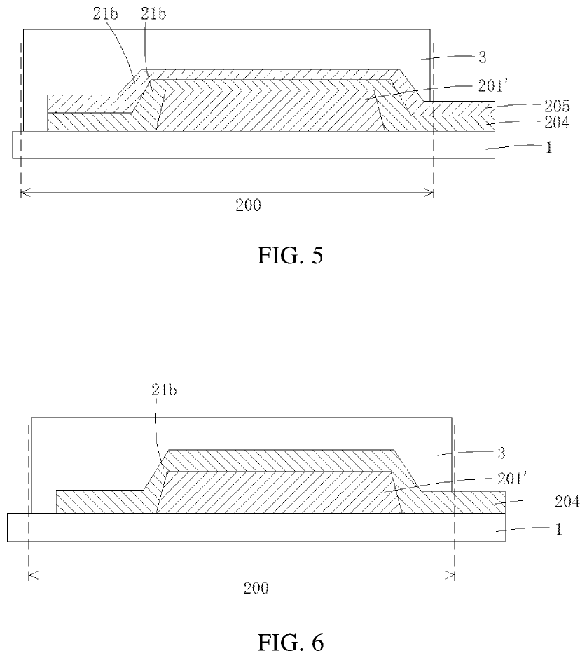

FIG. 5 is a structural schematic diagram of a third kind of the sealant region of the array substrate provided by one embodiment of the present invention.

FIG. 6 is a structural schematic diagram of a fourth kind of the sealant region of the array substrate provided by one embodiment of the present invention.

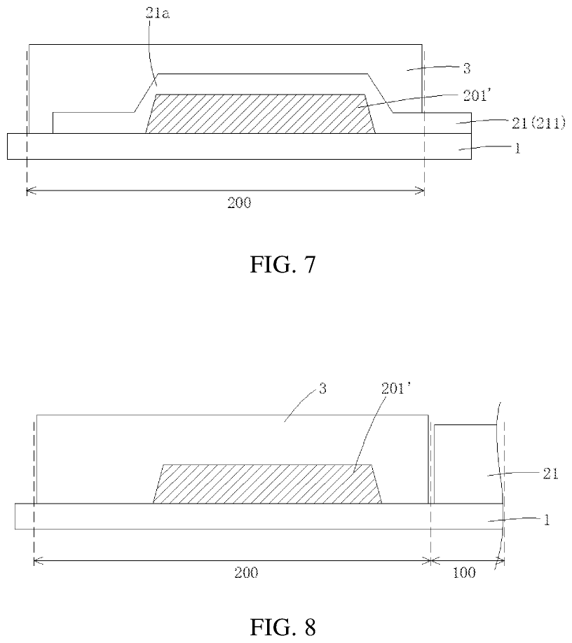

FIG. 7 is a structural schematic diagram of a fifth kind of the sealant region of the array substrate provided by one embodiment of the present invention.

FIG. 8 is a structural schematic diagram of a sixth kind of the sealant region of the array substrate provided by one embodiment of the present invention.

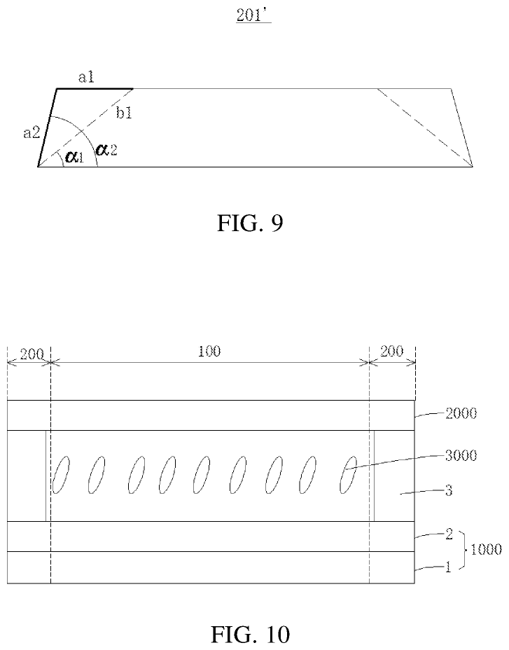

FIG. 9 is sectional schematic diagram of a conductive pattern provided by one embodiment of the present invention.

FIG. 10 is a structural schematic diagram of a liquid crystal display panel provided by one embodiment of the present invention.

### EMBODIMENTS OF THE PRESENT DISCLOSURE

### Detailed Description of Preferred Embodiments

The technical solutions in the embodiments of the present invention are clearly and completely described in the following with reference to the accompanying drawings in the embodiments of the present invention. Obviously, the described embodiments are only part of the embodiments of the present invention, but are not all embodiments of the present invention. All other embodiments obtained by those skilled in the art based on the embodiments of the present invention without creative efforts are within the scope of the present invention. Besides, it should be understood that the specific embodiments described herein are merely for describing and explaining the present invention and are not intended to limit the present invention. In the present invention, unless opposite stated, the orientation words used such as “upper” and “lower” generally refer to the upper and lower directions of the device in actual using or working state, and specifically refer to the drawing directions in the drawings, and “inner” and “outer” refer to the outline of the device.

Please refer to FIG. 2 to FIG. 8. One embodiment of the present invention provides an array substrate, which includes a device region 100 corresponding to a display region and a sealant region 200 enclosing the device region 100. The sealant region 200 is configured to bond to a sealant. The device region 100 is a region enclosed by the sealant region 200. The array substrate further includes a substrate 1 and an array driving layer 2 disposed on the substrate 1. The substrate 1 can be a flexible substrate or a rigid substrate. The array substrate 2 includes at least one conductive layer 20 and at least one insulation layer 20 located on a side of the at least one conductive layer 21 away from the substrate 1. The at least one conductive layer 20 includes a conductive pattern 201′ located in the sealant region 200. Wherein, the insulation layer 21 is only located in the device region 100 correspondingly; or the insulation layer 21 is correspondingly located in the device region 100 and the sealant region 200, and a number of layers of the insulation layer 21 located in the sealant region 200 is less than a number of layers of the insulation layer 21 located in the device region 100.

It can be understood that when only one layer of the insulation layer 21 is disposed on the side of the conductive layer 20 away from the substrate 1, the number of the layers of the insulation layer 21 located in the sealant region 200 is 0, i.e., the insulation layer 21 is not disposed corresponding to the sealant region 200, and the insulation layer 21 is only disposed in the device region 100.

Because the conductive pattern 201′ itself has a certain thickness, a height difference can be formed with the substrate 1 or the film layer under the conductive pattern 201′. The height difference can increase the contact area between the sealant and the array substrate. However, as the number of film layers on the conductive pattern 201′ increases, a climbing effect (i.e., height difference) of the film layers at the position corresponding to the conductive pattern 201′ can be gradually decreased. On the basis of this, in embodiments of the present invention, by not disposing the insulation layer 21 in the sealant region 21 or reducing the layer number of the film layers (insulation layer) on the conductive pattern 201′ located in the sealant region 200, and by using the level difference formed by the conductive pattern 201′, the contact area between the sealant and the array substrate is increased, thereby improving adhesive force between the sealant and the array substrate, so that the problem of insufficient adhesive force between the sealant and the array substrate is solved.

The array substrate and the liquid crystal display panel of the present invention will be further described in detail as follow with reference to specific embodiments, and the specific descriptions are as follows.

Please refer to FIG. 2. An array substrate provided by one embodiment of the present invention includes a device region 100 corresponding to a display region and a sealant region 200 enclosing the device region 100. The array substrate includes a substrate 1 and an array driving layer 2 located on the substrate 1. The array driving layer 2 extends from the device region 100 to the sealant region 200. Wherein, the array driving layer 2 includes a conductive layer 20 and an insulation layer 21 disposed in a stack.

Specifically, a part of the array driving layer 2 corresponding to the device region 100 includes a gate electrode 201, a gate insulation layer 211, an active layer 22, an interlayer insulation layer 212, a source-drain electrode 202, a passivation layer 213, a pixel electrode 203, and a planarization layer 214 disposed in a stack from bottom to top. The gate electrode 201, the active layer 22, and the source-drain electrode 202 form a thin film transistor. The pixel electrode 203 is electrically connected to the drain electrode through a via hole in the passivation layer 213. A part of the array driving layer 2 corresponding to the sealant region 200 includes a buffer layer 22, a conductive pattern 201′, the gate insulation layer 211, the interlayer insulation layer 212, and the passivation layer 213 disposed in a stack from bottom to top.

It should be noted that the thin film transistor in the device region 100 illustrated in FIG. 2 is a bottom-gate structure. Of course, in other embodiments of the present invention, the thin film transistor can be a top-gate structure or a double-gate structure, which is not limited herein. In addition, according to actual requirements, the array substrate of the present invention can also include other conventional film layers, such as a buffer layer, a common electrode layer, a color resist layer, an alignment film, etc., and can also further include capacitors, signal lines, etc.

Wherein, a number of layers of the insulation layer 21 located in the sealant region 200 is less than a number of layers of the insulation layer 21 located in the device region 100. Specifically, in this embodiment, the number of the layers of the insulation layer 21 located in the sealant region 200 is three, and the number of the layers of the insulation layer 21 located in the device region 100 is four.

It should be noted that, in one embodiment of the present invention, the gate electrode 201 and the conductive pattern 201′ are located in a same layer, the gate electrode 201 and the conductive pattern 201′ can be film layers formed of a same material and formed by a same process, or the film layers formed of different materials and different processes, or the film layers formed of a same material but formed by different processes. In addition, the gate insulation layer 211, the interlayer insulation layer 212, and the passivation layer 213 corresponding to the sealant region 200, and the gate insulation layer 211, the interlayer insulating layer 212, and the passivation layer 213 corresponding to the device region 100 are respectively film layers formed by a same material and same processes. Wherein, film layer thicknesses of a part corresponding to the sealant region 200 and a part corresponding to the device region 100 of a same film layer are uniform.

Wherein, in the sealant region 200, a surface area of the array driving layer 2 is greater than a projection area of an orthogonal projection of the array driving layer 2 on the substrate 1. Specifically, in the sealant region 200, an area of a surface of the array driving layer 2 facing away from the substrate 1 is greater than the projection area of the orthogonal projection of the array driving layer 2 on the substrate 1. Therefore, when the sealant is bonded to the part of the sealant region 200 of the array substrate, as the actual contact area between the sealant and the array substrate increases, the adhesive force between the sealant and the array substrate is improved, which can solve the problem of insufficient adhesive force between the sealant and the array substrate.

Furthermore, in the sealant region 200, due to a thickness of the conductive pattern 201′ itself, each layer of the insulation layer 21 forms a first coverage layer 21a at a position corresponding to the conductive pattern 201′, and a surface area of each first coverage layer 21a is greater than a projection area of an orthogonal projection of the first coverage layer 21a on the substrate 1.

In this embodiment, as one layer of the insulation layer 21 (214) is reduced in the sealant region 200, and the conductive pattern 201′ is used to make the passivation layer 213 form the first coverage layer 21a, the contact area between the sealant and the array substrate (passivation layer 213) can be increased, thereby improving the adhesive force between the sealant and the array substrate.

Furthermore, in the sealant region 200, a distance of a boundary of the insulation layer 21 to the device region 100 is less than a distance of a boundary on a side of the sealant region 200 away from the device region 100 to the device region 100, and the orthogonal projection of the insulation layer 21 on the substrate 1 covers the orthogonal projection of the conductive pattern 201′ on the substrate 1.

That is, in the sealant region 200, the sealant can directly contact to the substrate 1 along the lateral surface of a plurality of layers of the insulation layer 21. Therefore, the contact area between the sealant and the array substrate can be further increased, thereby further improving the adhesive force between the sealant and the array substrate.

Please refer to FIG. 3 and FIG. 4. In some embodiments of the present invention, in the sealant region 200 of the array substrate, two conductive layers and one insulation layer located on the substrate 1 are included. The two conductive layers can be conductive layers in a same layer with any two of the gate electrode 201, the source-drain electrode 202, or the pixel electrode 203. One layer of the insulation layer can be any one of the gate insulation layer 211, the interlayer insulation layer 212, the passivation layer 213, or the planarization layer 214.

Specifically, as illustrated in FIG. 3, as one embodiment, the sealant region 200 includes the substrate 1, the conductive pattern 201′, the gate insulation layer 211, a first conductive pattern 204, and a sealant 3 sequentially disposed in a stack from bottom to top. Wherein, the conductive pattern 201′ is in a same layer with the gate electrode 201, and the first conductive pattern 204 is in a same layer with the source-drain electrode 202.

As illustrated in FIG. 4, as one embodiment, the sealant region 200 includes the substrate 1, the conductive pattern 201′, the first conductive pattern 204, the passivation layer 213, and the sealant 3 sequentially disposed in a stack from bottom to top. Wherein, the conductive pattern 201′ is in a same layer with the gate electrode 201, and the first conductive pattern 204 is in a same layer with the source-drain electrode 202.

Please continue referring to FIG. 3 and FIG. 4. In the sealant region 200, an area of a surface of the array driving layer facing away from the substrate 1 is greater than the projection area of the orthogonal projection of the array driving layer on the substrate 1.

Specifically, the gate insulation layer 211 or the passivation layer 213 includes a first coverage layer 21a corresponding to the conductive pattern 201′. The surface area of the first coverage layer 21a is greater than a projection area of an orthogonal projection of the first coverage layer 21a on the substrate 1. The first conductive pattern 204 includes a second coverage layer 21b corresponding to the conductive pattern 201′, and a surface area of the second coverage layer 21b is greater than a projection area of an orthogonal projection of the second coverage layer 21b on the substrate 1. Therefore, the contact area between the sealant 3 and the array substrate can be increased, thereby improving the adhesive force between the sealant 3 and the array substrate.

Furthermore, as one side of the sealant 3 away from the device region 100 can directly contact to the substrate 1 along the lateral surfaces of the first conductive pattern 204 and the gate insulation layer 211, or the side of the sealant 3 away from the device region 100 can directly contact to the substrate 1 along the lateral surfaces of the passivation layer 213 and the first conductive pattern 204, so the contact area between the sealant 3 and the array substrate can be further increased.

Please refer to FIG. 5, in one embodiment of the present invention, the sealant region 200 of the array substrate includes three layers of the conductive layers on the substrate 1, and the insulation layer is not correspondingly disposed in the sealant region 200 in this embodiment. Specifically, the sealant region 200 includes the substrate 1, the conductive pattern 201′, the first conductive pattern 204, the second conductive pattern 205, and the sealant 3 sequentially disposed in a stack from bottom to top. Wherein, the conductive pattern 201′ is in a same layer with the gate electrode 201, the first conductive pattern 204 is in a same layer with the source-drain electrode 202, and the second conductive pattern 205 is in a same layer with the pixel electrode 203. Orthogonal projections of the first conductive pattern 204 and the second conductive pattern 205 on the substrate 1 cover the orthogonal projection of the conductive pattern 201′ on the substrate 1.

Wherein, the first conductive pattern 204 and the second conductive pattern 205 both include a second coverage layer 21b corresponding to the conductive pattern 201′, and a surface area of the second coverage layer 21b is greater than a projection area of an orthogonal projection of the second coverage layer 21b on the substrate 1. Therefore, the contact area between the sealant 3 and the array substrate can be increased, thereby improving the adhesive force between the sealant 3 and the array substrate.

Furthermore, as one side of the sealant 3 away from the device region 100 can directly contact to the substrate 1 along the lateral surfaces of the first conductive pattern 204 and the second conductive pattern 205, the contact area between the sealant 3 and the array substrate can be further increased.

Please refer to FIG. 6, in some embodiments of the present invention, in the sealant region 200 of the array substrate, two layers of the conductive layers on the substrate 1 are included, and the insulation layer is not correspondingly disposed in the sealant region 200. The two conductive layers can be conductive layers in a same layer with any two of the gate electrode 201, the source-drain electrode 202, or the pixel electrode 203. Specifically, the sealant region 200 includes the substrate 1, the conductive pattern 201′, the first conductive pattern 204, and the sealant 3 sequentially disposed in a stack from bottom to top.

As one embodiment, the conductive pattern 201′ is in a same layer with the gate electrode 201, and the first conductive pattern 204 is in a same layer with the source-drain electrode 202. The orthogonal projection of the first conductive pattern 204 on the substrate 1 covers the orthogonal projection of the conductive pattern 201′ on the substrate 1.

Wherein, the first conductive pattern 204 includes a second coverage layer 21b corresponding to the conductive pattern 201′, and a surface area of the second coverage layer 21b is greater than a projection area of an orthogonal projection of the second coverage layer 21b on the substrate 1. Therefore, the contact area between the sealant 3 and the array substrate can be increased, thereby improving the adhesive force between the sealant 3 and the array substrate.

Furthermore, as one side of the sealant 3 away from the device region 100 can directly contact to the substrate 1 along the lateral surface of the first conductive pattern 204, the contact area between the sealant 3 and the array substrate can be further increased.

Please refer to FIG. 7. In some embodiments of the present invention, in the sealant region 200 of the array substrate, one conductive layer and one insulation layer located on the substrate 1 are included. The one conductive layer can be a conductive layer in a same layer with any one of the gate electrode 201, the source-drain electrode 202, or the pixel electrode 203. One layer of the insulation layer can be any one of the gate insulation layer 211, the interlayer insulation layer 212, the passivation layer 213, or the planarization layer 214. Specifically, the sealant region 200 includes the substrate 1, the conductive pattern 201′, the insulation layer 21, and the sealant 3 sequentially disposed in a stack from bottom to top.

As one embodiment, the conductive pattern 201′ is in a same layer with the gate electrode 201, and the insulation layer 21 is in a same layer with the gate insulation layer 211. An orthogonal projection of the gate insulation layer 211 on the substrate 1 covers the orthogonal projection of the conductive pattern 201′ on the substrate 1.

Wherein, the gate insulation layer 211 includes a first coverage layer 21a corresponding to the conductive pattern 201′, and the surface area of the first coverage layer 21a is greater than a projection area of an orthogonal projection of the first coverage layer 21a on the substrate 1. Therefore, the contact area between the sealant 3 and the array substrate can be increased, thereby improving the adhesive force between the sealant 3 and the array substrate.

Furthermore, as one side of the sealant 3 away from the device region 100 can directly contact to the substrate 1 along the lateral surface of the gate insulation layer 211, the contact area between the sealant 3 and the array substrate can be further increased.

Please refer to FIG. 8, in some embodiments of the present invention, in the sealant region 200 of the array substrate, one conductive layer located on the substrate 1 is included. An orthogonal projection of the insulation layer 21 on the substrate 1 is within the device region 100, i.e., the insulation layer 21 is not disposed in the sealant region 200. Wherein, the one conductive layer can be a conductive layer in a same layer with any one of the gate electrode 201, the source-drain electrode 202, or the pixel electrode 203. Specifically, the sealant region 200 includes the substrate 1, the conductive pattern 201′, and the sealant 3 sequentially disposed in a stack from bottom to top.

As one embodiment, the conductive pattern 201′ is in a same layer with the gate electrode 201.

Wherein, disposing the conductive pattern 201′ can increase the contact area between the sealant 3 and the array substrate, thereby improving the adhesive force between the sealant 3 and the array substrate.

It should be noted that, in the plurality of aforesaid embodiments of the present invention, the conductive layer 20 can include, but is not limited to, at least one metal material of or more than one alloy of Mo, Cu, Ti, or Al. In the sealant region 200, on the substrate 1, a conductive pattern formed of a layer of the conductive layer 20 can be included, or a laminated conductive pattern formed of at least two layers of the conductive layer 20 can also be included. Wherein, a thickness of one layer of the conductive pattern or the laminated conductive patterns ranges from 1000 angstroms to 20000 angstroms. In addition, when the aforesaid material is adopted in the conductive layer 20, the adhesive performance after the sealant 3 directly in contacts to the conductive layer 20 is better.

Please refer to FIG. 9. In the plurality of aforesaid embodiments of the present invention, the conductive pattern 201′ includes a bottom surface facing toward the substrate and a lateral surface connected to the bottom surface, an included angle α2 formed between the lateral surface and the bottom surface ranges from 60°-90°. Generally, in manufacturing processes of the array substrate, a bottom angle (such as α1) of a pattern formed after the conductive layer is etched is less than 60°. In one embodiment of the present invention, the contact area between the sealant and the array substrate is increased by increasing the included angle between the lateral surface and the bottom surface of the conductive pattern 201′. For example, the included angle α1 ranges from 10° to 60°, and the included angle α2 ranges from 60° to 90°. According to a sum of two sides of a triangle is greater than a third side, it is known that a sum of areas of a contact surface a1 and a contact surface a2 is greater than an area of a contact surface b1. Therefore, the larger the included angle between the lateral surface and the bottom surface of the conductive pattern 201′ is, the larger the contact area between the sealant and the array substrate is.

Please refer to FIG. 2 to FIG. 10. One embodiment of the present invention further provides a liquid crystal display panel, including the aforesaid array substrate 1000, and further including an opposite substrate 2000 disposed opposite to the array substrate 1000, a liquid crystal layer 3000 located between the array substrate 1000 and the opposite substrate 2000, and the sealant 3 for bonding the array substrate 1000 and the opposite substrate 2000. Wherein, the sealant 3 is bonded to a part of the array substrate 1000 corresponding to the sealant region 200.

Wherein, a contact area between the array substrate 1000 and the sealant 3 is greater than an orthogonal projection of the sealant 3 on the array substrate 1000. Therefore, adhesive force between the sealant 3 and the array substrate 1000 is improved.

Furthermore, as the part of the sealant 3 away from the device region 100 directly contacts to the substrate 1 along the lateral surfaces of the conductive layer 20 and/or the insulation layer 21, the contact area between the sealant 3 and the array substrate 1000 is further increased, thereby further improving the adhesive force between the sealant 3 and the array substrate 1000.

In one embodiment, an orthogonal projection of the insulation layer 21 on the substrate 1 is within the device region 100, i.e., the insulation layer 21 is not disposed at the position of the array substrate 1000 corresponding to the sealant region 200; at least one conductive layer 20 forms a conductive pattern in the sealant region 200, and the conductive pattern can increase the contact area between the sealant 3 and the array substrate 1000. The specific can refer to the description to the array substrate mentioned above, and redundant description will not be mentioned herein again.

In summary, in the array substrate and the liquid crystal display panel provided by the present invention, by reducing the number of the layers of the insulation layer located on the conductive pattern in the sealant region, and by using the level difference formed by the conductive pattern, the contact area between the sealant and the array substrate is increased, thereby improving adhesive force between the sealant and the array substrate, so that the problem of insufficient adhesive force between the sealant and the array substrate is solved.

The above describes the embodiments of the present invention in detail. This article uses specific cases for describing the principles and the embodiments of the present invention, and the description of the embodiments mentioned above is only for helping to understand the method and the core idea of the present invention. Meanwhile, for those skilled in the art, will have various changes in specific embodiments and application scopes according to the idea of the present invention. In summary, the content of the specification should not be understood as limit to the present invention.

What is claimed is:

1. An array substrate, having a device region and a sealant region enclosing the device region, wherein the array substrate comprises:
a substrate;
an array driving layer disposed on the substrate, wherein the array substrate comprises at least one of conductive layers and at least one insulation layer located on a side of at least one of the conductive layers away from the substrate, and the at least one of the conductive layers comprises a conductive pattern located in the sealant region; and
wherein the insulation layer is only located in the device region correspondingly; or the insulation layer is correspondingly located in the device region and the sealant region, and a number of layers of the insulation layer located in the sealant region is less than a number of layers of the insulation layer located in the device region.

2. The array substrate as claimed in claim 1, wherein a surface area of the array driving layer is greater than a projection area of an orthogonal projection of the array driving layer on the substrate in the sealant region.

3. The array substrate as claimed in claim 2, wherein in the sealant region, the at least one insulation layer is disposed on a side of the conductive pattern away from the substrate, the insulation layer comprises a first coverage layer corresponding to the conductive pattern, a surface area of the first coverage layer is greater than a projection area of an orthogonal projection of the first coverage layer on the substrate.

4. The array substrate as claimed in claim 2, wherein in the sealant region, at least one of the conductive layers is disposed on the side of the conductive pattern away from the substrate, at least one of the conductive layers comprises a second coverage layer corresponding to the conductive pattern, and a surface area of the second coverage layer is greater than a projection area of an orthogonal projection of the second coverage layer on the substrate.

5. The array substrate as claimed in claim 3, wherein in the sealant region, at least one of the conductive layers is disposed on the side of the conductive pattern away from the substrate, at least one of the conductive layers comprises a second coverage layer corresponding to the conductive pattern, and a surface area of the second coverage layer is greater than a projection area of an orthogonal projection of the second coverage layer on the substrate.

6. The array substrate as claimed in claim 1, wherein in the sealant region, a distance of a boundary of the insulation layer to the device region is less than a distance of a boundary on a side of the sealant region away from the device region to the device region, and an orthogonal projection of the insulation layer on the substrate covers an orthogonal projection of the conductive pattern on the substrate; or
in the sealant region, at least one of the conductive layers is disposed on a side of the conductive pattern away from the substrate, a distance of a boundary of at least one of the conductive layers to the device region is less than the distance of the boundary on the side of the sealant region away from the device region to the device region, and the orthogonal projection of the insulation layer on the substrate covers the orthogonal projection of the conductive pattern on the substrate.

7. The array substrate as claimed in claim 1, wherein the conductive pattern comprises a bottom surface facing toward the substrate and a lateral surface connected to the bottom surface, an included angle formed between the lateral surface and the bottom surface ranges from 60°-90°.

8. A liquid crystal display panel, comprising the array substrate as claimed in claim 1, and comprising an opposite substrate disposed opposite to the array substrate, a liquid crystal layer located between the array substrate and the opposite substrate, and a sealant for bonding the array substrate and the opposite substrate;
wherein the sealant is bonded to a part of the array substrate corresponding to the sealant region.

9. The liquid crystal display panel as claimed in claim 8, wherein a contact area between the array substrate and the sealant is greater than a projection area of an orthogonal projection of the sealant on the array substrate.

10. The liquid crystal display panel as claimed in claim 9, wherein in the sealant region, the at least one insulation layer is disposed on a side of the conductive pattern away from the substrate, the insulation layer comprises a first coverage layer corresponding to the conductive pattern, a surface area of the first coverage layer is greater than a projection area of an orthogonal projection of the first coverage layer on the substrate.

11. The liquid crystal display panel as claimed in claim 10, wherein in the sealant region, at least one of the conductive layers is disposed on the side of the conductive pattern away from the substrate, at least one of the conductive layers comprises a second coverage layer corresponding to the conductive pattern, and a surface area of the second coverage layer is greater than a projection area of an orthogonal projection of the second coverage layer on the substrate.

12. The liquid crystal display panel as claimed in claim 9, wherein a part of the sealant away from the device region contact to the substrate along at least one of the conductive layers and the lateral surface of the insulation layer; or the part of the sealant away from the device region contact to the substrate along at least one of the conductive layers or the lateral surface of the insulation layer.

13. The liquid crystal display panel as claimed in claim 9, wherein an orthogonal projection of the insulation layer on the substrate is within the device region, and the sealant directly contacts to at least one of the conductive layers.

14. The liquid crystal display panel as claimed in claim 8, wherein the conductive pattern comprises a bottom surface facing toward the substrate and a lateral surface connected to the bottom surface, an included angle formed between the lateral surface and the bottom surface ranges from 60°-90°.

15. An array substrate, having a device region and a sealant region enclosing the device region, wherein the array substrate comprises:
a substrate;
an array driving layer disposed on the substrate, wherein the array substrate extends from the device region to the sealant region, the array substrate comprises at least one of conductive layers and at least one insulation layer located on a side of at least one of the conductive layers away from the substrate, and at least one of the conductive layers comprises a conductive pattern located in the sealant region; and
wherein the insulation layer is only located in the device region correspondingly; or the insulation layer is correspondingly located in the device region and the sealant region, and a number of layers of the insulation layer located in the sealant region is less than a number of layers of the insulation layer located in the device region.

16. The array substrate as claimed in claim 15, wherein a surface area of the array driving layer is greater than a projection area of an orthogonal projection of the array driving layer on the substrate in the sealant region.

17. The array substrate as claimed in claim 16, wherein in the sealant region, the at least one insulation layer is disposed on a side of the conductive pattern away from the substrate, the insulation layer comprises a first coverage layer corresponding to the conductive pattern, a surface area of the first coverage layer is greater than a projection area of an orthogonal projection of the first coverage layer on the substrate.

18. The array substrate as claimed in claim 16, wherein in the sealant region, at least one of the conductive layers is disposed on the side of the conductive pattern away from the substrate, at least one of the conductive layers comprises a second coverage layer corresponding to the conductive pattern, and a surface area of the second coverage layer is greater than a projection area of an orthogonal projection of the second coverage layer on the substrate.

19. The array substrate as claimed in claim 15, wherein in the sealant region, a distance of a boundary of the insulation layer to the device region is less than a distance of a boundary on a side of the sealant region away from the device region to the device region, and an orthogonal projection of the insulation layer on the substrate covers an orthogonal projection of the conductive pattern on the substrate; or
in the sealant region, at least one of the conductive layers is disposed on a side of the conductive pattern away from the substrate, a distance of a boundary of at least one of the conductive layers to the device region is less than the distance of the boundary on the side of the sealant region away from the device region to the device region, and the orthogonal projection of the insulation layer on the substrate covers the orthogonal projection of the conductive pattern on the substrate.

20. The array substrate as claimed in claim 15, wherein the conductive pattern comprises a bottom surface facing toward the substrate and a lateral surface connected to the bottom surface, an included angle formed between the lateral surface and the bottom surface ranges from 60°-90°.
